(19) United States
(12) Patent Application Publication
(10) Pub. No.: US 2026/0295637 A1
(43) Pub. Date: Oct. 1, 2026

(54) SEMICONDUCTOR DEVICE WITH IMPROVED DIELECTRIC FILM STRUCTURE AND METHOD OF MANUFACTURING SAME

(71) Applicant: Taiwan Semiconductor Manufacturing Company, LTD., Hsinchu (TW)

(72) Inventors: Kang-Yi Lien, Tainan (TW); Kuan-Chi Tsai, Kaohsiung (TW); Yi-Chieh Huang, Tainan (TW); Hsiang-Fu Chen, Zhubei (TW); Chia-Ming Hung, Taipei (TW); I-Hsuan Chiu, Taipei (TW)

(21) Appl. No.: 19/709,106

(22) Filed: Jun. 16, 2026

Related U.S. Application Data
(62) Division of application No. 17/688,042, filed on Mar. 7, 2022.

(51) Int. Cl. B06B 1/02; B81B 7/00

(52) U.S. Cl. CPC B06B 1/0292; B81B 7/0016

(57) ABSTRACT

A semiconductor device and method of manufacturing the same that utilizes dielectric pedestals on a sensing electrode. The semiconductor device includes a one or more membranes and an integrated circuit substrate. The integrated circuit substrate includes one or more conductive components disposed within a first dielectric layer on the substrate, with the conductive components interconnected with respective integrated circuit components. The substrate further includes one or more sensing electrodes electrically coupled to the conductive components, and one or more dielectric pedestals positioned within a landing area of the sensing electrode. In addition, the semiconductor device includes at least one cavity that is formed by the membrane positioned over the sensing electrode.

### PRIORITY CLAIM AND CROSS-REFERENCE

This application is a Divisional of U.S. patent application Ser. No. 17/688,042, filed Mar. 7, 2022, and titled SEMICONDUCTOR DEVICE WITH IMPROVED DIELECTRIC FILM STRUCTURE AND METHOD OF MANUFACTURING SAME, which is incorporated herein by reference in its entirety.

### BACKGROUND

Micro-electro-mechanical systems (MEMS) is a technology that utilizes miniature mechanical and electromechanical elements (e.g., devices or structures) on an integrated circuit substrate. MEMS devices may range from relatively simple structures with no moving elements, to complex electro-mechanical systems utilizing a variety of moving elements under the control of an integrated microelectronic controller. The devices or structures that are used in MEMS include microsensors, micro-actuators, microelectronics, and microstructures. MEMS devices may be used in a wide range of applications, including, for example and without limitation, motion sensors, pressure sensors, inertial sensors, micro-fluidic devices (e.g., valves, pumps, nozzle controls), optical devices, imaging devices (e.g., micromachined ultrasonic transducers (“MUT” )), capacitive MUT (“CMUT”) ultrasound transducers, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is simplified side view of a bottom/sensing electrode component having dielectric pedestals utilized in a CMUT device, in accordance with some embodiments.

FIG. 1B is a simplified top view of the bottom/sensing electrode component of FIG. 1A.

FIGS. 2A-2J illustrate cross-sectional views of some steps for forming a CMUT unit utilizing a pedestal arrangement in accordance with some embodiments.

FIG. 3 illustrates a cross-sectional view of a CMUT unit utilizing a pedestal dielectric arrangement in accordance with some embodiments.

FIG. 4 illustrates a cross-sectional view of a CMUT unit utilizing dielectric pedestals in accordance with some embodiments.

FIG. 5A is simplified side view of a bottom/sensing electrode component having isolation pedestals utilized in a CMUT device, in accordance with some embodiments.

FIG. 5B is a simplified top view of the bottom/sensing electrode component of FIG. 5A.

FIG. 6 illustrates a cross-sectional view of a CMUT unit utilizing an isolation pedestal arrangement in accordance with some embodiments.

FIG. 7 illustrates a cross-sectional view of a CMUT unit utilizing isolation pedestals in accordance with some embodiments.

FIG. 8 illustrates a method for pedestal formation on a bottom/sensing electrode of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

In some embodiments, a semiconductor device (e.g., integrated chip) comprises a microelectromechanical systems (MEMS) device. The MEMS device comprises a cavity and a movable membrane. The configuration (e.g., structural configuration) of the MEMS device is dependent on the type of MEMS device. The present disclosure discusses structures and fabrication methods of a capacitive MUT (CMUT). The CMUT device is widely used in high-resolution applications, e.g., medical diagnostics, imaging, sensors, etc., as well as air-coupled non-destructive evaluation, ultrasonic flow meters for narrow gas pipelines, microphones with RF detection, Lamb wave devices, smart microfluidic channels, and the like. Current production of CMUTs utilizes a bottom electrode covered by a dielectric film, with the movable membrane spaced apart from the bottom electrode by a gap (thus, the cavity of the CMUT is located between the movable membrane and the bottom electrode). The movable membrane carries a top electrode, so that movement of the membrane in response to sonic waves creates a variable capacitance between the bottom and top electrodes, thus providing an acoustic transducer. (Conversely, an AC electrical signal applied across the top and bottom electrodes can cause the membrane to oscillate and generate an acoustic wave). However, as the membrane of the CMUT moves, it may come into contact with (i.e. “clap” on) the bottom electrode with a large contact area (dielectric film) during operations of the CMUT. This large contact area may cause the CMUT device to suffer stiction issues. In addition, the small separation between the top and bottom electrodes at the contacting region generates a transitory high electric field at the contacting region for the duration of the clap event, and consequently a high accumulated electrical charge at the contacting region. These factors can lead to premature breakdown of the device. Embodiments disclosed herein employ a different, “pattern first” process that mitigates these problems.

In particular, the present disclosure alleviates the stiction and premature breakdown issues of a CMUT device. That is, by utilizing a set of pedestals of (or alternatively, disposed on) the dielectric material covering the bottom electrode, the landing area of the dielectric material contacting the membrane during a clap event decreases, reducing stiction as the membrane vibrates. The pedestals also increase the separation between the bottom and top electrodes thus reducing the magnitude of the electric field during the clap event. The pedestal pattern may reduce both of the top and bottom electrode contact surface, and increase the bottom/top electrode separation, thereby minimizing charging accumulation. In some embodiments, the CMUT acoustic decay performance is also improved, since stiction of the membrane can artificially damp the acoustic vibration of the membrane and the pedestals reduce the stiction.

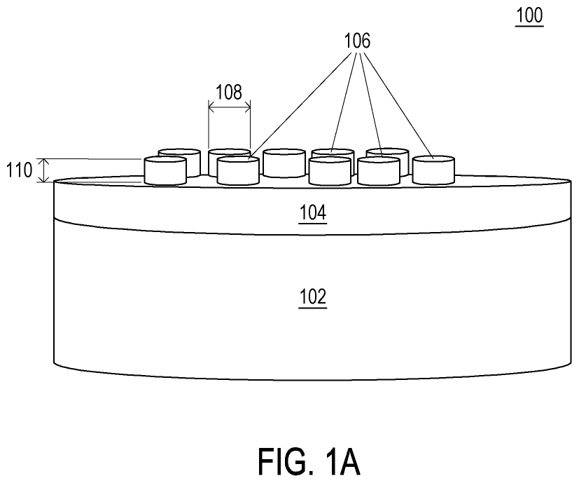

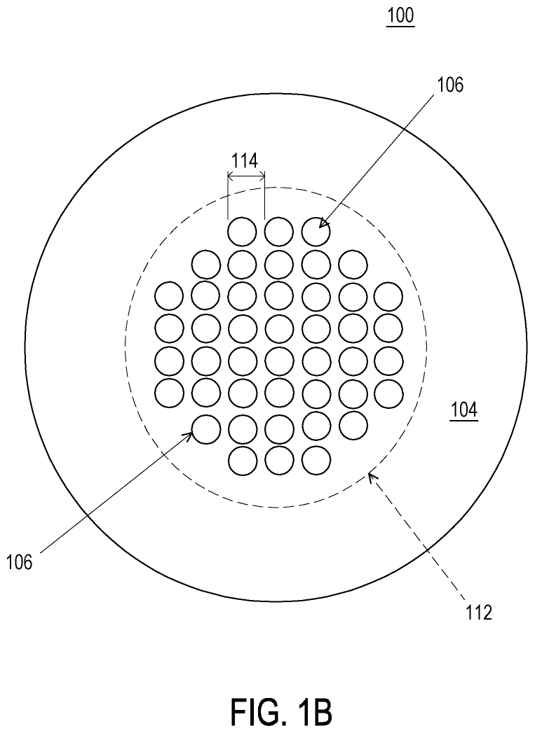

Turning now to FIGS. 1A-1B, there is shown a simplified side view of a bottom/sensing electrode component 100 utilized in a CMUT device (FIG. 1A) and a simplified top view of the bottom/sensing electrode component 100 (FIG. 1B) in accordance with some embodiments disclosed herein. As illustrated in FIG. 1A, the bottom/sensing electrode component 100 is depicted comprising a bottom/sensing electrode 102, a pedestal dielectric layer 104 and one or more pedestals 106, disposed on the pedestal dielectric layer 104. In accordance with some embodiments, each pedestal 106 has a pedestal diameter (“P”) 108 and a pedestal height (“H”) 110, thereby defining an aspect ratio of “H/P”. In some embodiments, the aspect ratio H/P may range from 0.025~0.2, e.g., H=0.1 micrometers and P=4 micrometers to H=0.1 micrometers and P=0.5 micrometers. It will be appreciated that the pedestal 106 is depicted as having a cylindrical profile for exemplary purposes only, and other profiles are equally contemplated herein, for example and without limitation, rectangular, polygonal, elliptical, button, ball, and the like. Furthermore, while illustrated as completely flat on the top surface, it will be appreciated by the skilled artisan that in some embodiments, the outer circumference (or edges of polygonal shapes) may be advantageously rounded, smoothed, or otherwise modified to ensure that no sharp edges, corners, etc., are present that may impact, damage, or degrade the membrane during operations of the CMUT device.

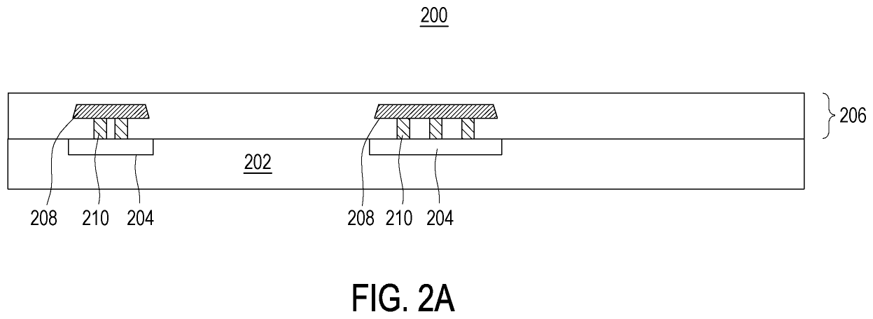

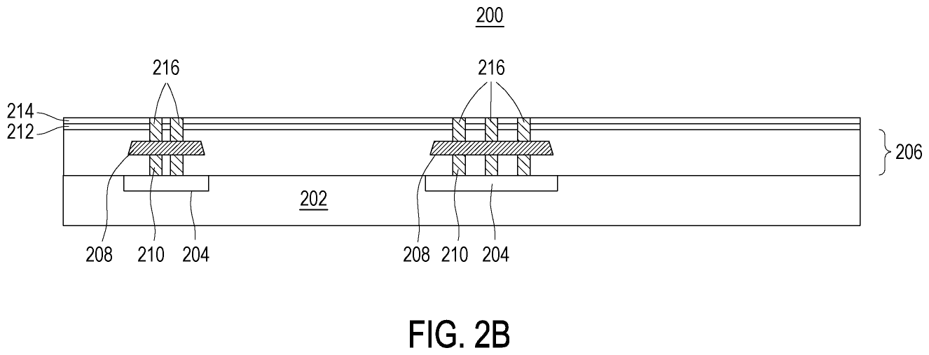

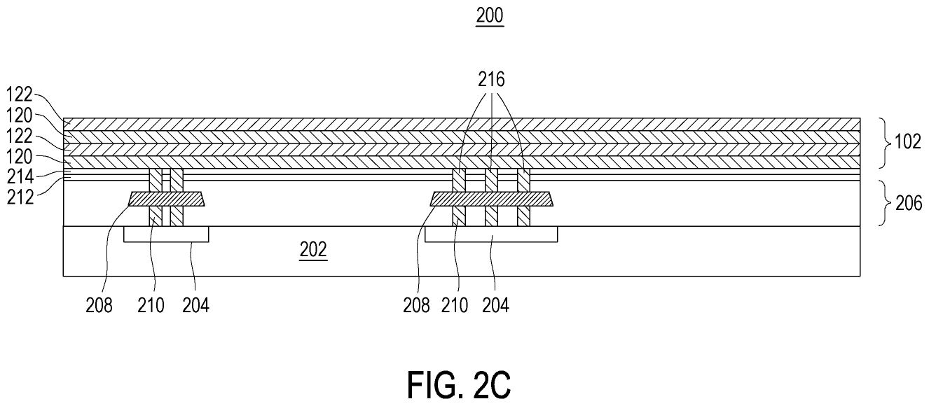

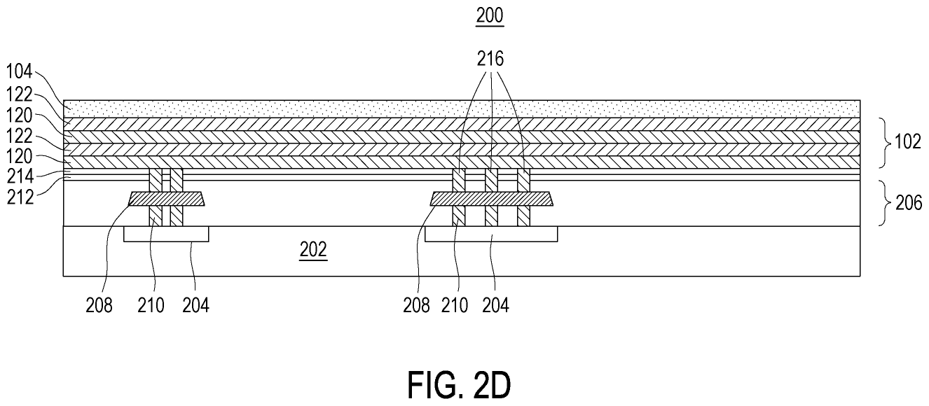

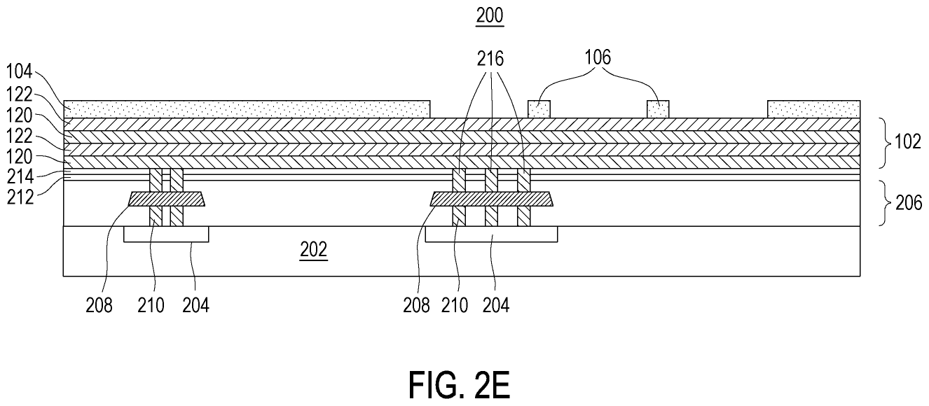

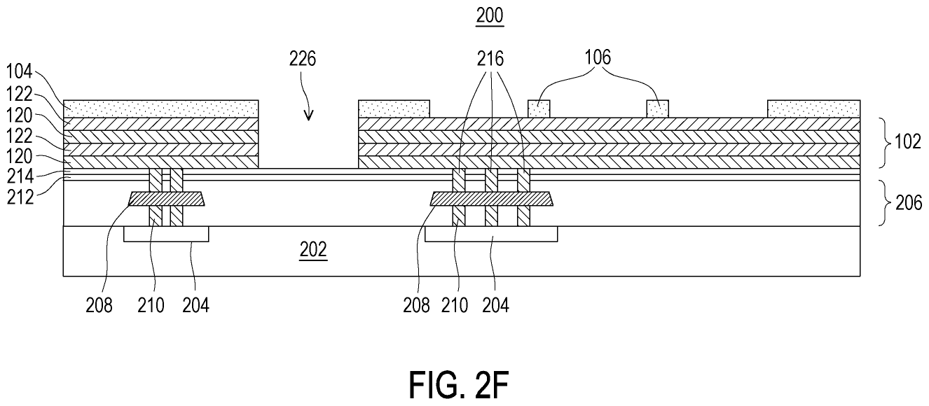

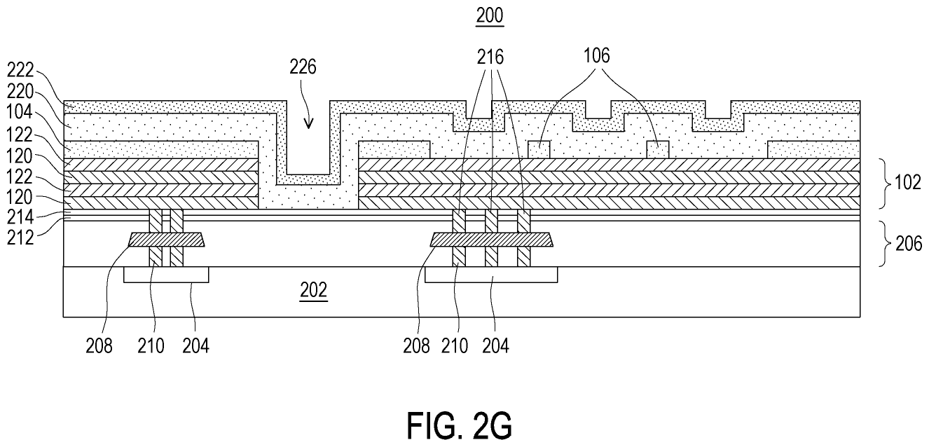

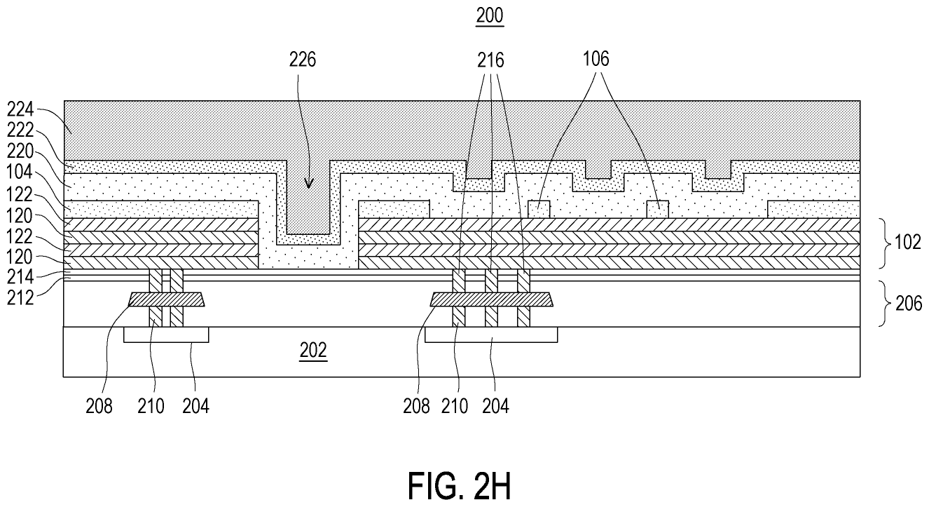

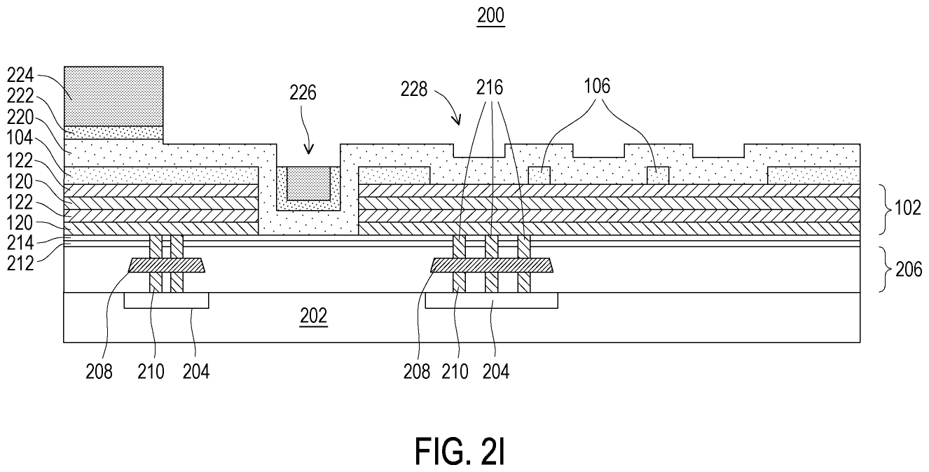

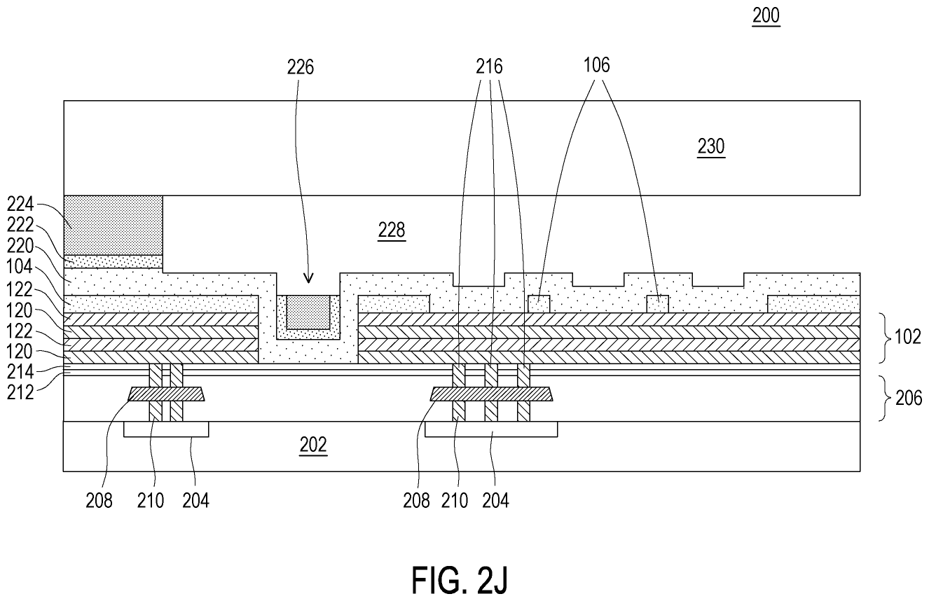

As shown in FIG. 1B, the one or more pedestals 106 are arranged within a landing area 112 of the pedestal dielectric layer 104. It will be appreciated that the landing area 112 corresponds to the surface area of the bottom/sensing electrode component 100 that has a high likelihood of contacting the movable membrane (not shown) of the CMUT device if a clap event occurs during operation of the CMUT device. Viewed another way, the landing area 112 is the area covered by the set of pedestals 106. Typically, the landing area 112 is located at a central region of the cavity of the CMUT device. In accordance with some exemplary embodiments, the landing area 112 may correspond to greater than or equal to 60% of the bottom/sensing electrode area, and a single pedestal 106 may define greater than or equal to 1.5% of such a landing area 112. That is, the top surface of the pedestal 106 that contacts the membrane during operations of the semiconductor device 200 (as shown in FIGS. 2J-7, below) has a surface area that is greater than or equal to 1.5% of the aforementioned landing area.

Also shown in FIG. 1B, the pattern of the pedestals 106 formed of the pedestal dielectric layer 104 utilizes a predetermined pedestal-to-pedestal spacing 114 corresponding to the spacing of pedestals 106 within the landing area 110. A pedestal-to-pedestal pitch ratio (“S”) can also be defined as a ratio of the pedestal diameter 108 (or other principal pedestal dimension) to the pedestal-to-pedestal spacing 114. In some embodiments, the pitch ratio S may be in the range of less than or equal to 80%, so as to minimize charging accumulation on the bottom/sensing electrode 102 during operations of the CMUT device. The formation of a CMUT semiconductor device 200 utilizing the dielectric pedestal design depicted in FIGS. 1A-1B is illustrated in greater detail below with respect to FIGS. 2A-2J.

Referring now to FIGS. 2A-2J, there are shown cross-sectional views of various stages of a method of manufacturing a CMUT semiconductor device/unit 200 in accordance with one embodiment. In the following, various layers or films are deposited and patterned. The patterning of a layer may employ any suitable patterning technique such as a photolithographic patterning technique using deposition of a photoresist layer and selective exposure via a photomask to visible light, ultraviolet light, deep ultraviolet light (i.e., DUV lithography), extreme ultraviolet light (i.e. EUV lithography), or so forth, followed by development of the exposed photoresist and subsequent etching, deposition or other process steps laterally delineated by the developed photoresist. In other embodiments, patterning of an electron-sensitive resist layer may be by way of electron beam exposure (electron beam lithography, i.e., e-beam lithography). The skilled artisan will appreciate that the foregoing are merely illustrative examples.

Turning now to FIG. 2A, an integrated circuit substrate 202 having one or more electrically conductive components 204 disposed therein is shown. In accordance with one embodiment, substrate 202 is an integrated circuit substrate, such as a complimentary metal-oxide semiconductor (“CMOS”) substrate and the one or more conductive components 204 are electrical circuit components of a CMOS circuit. In such an embodiment, the one or more conductive components 204 correspond to integrated circuit (“IC”) components that are disposed on or over the CMOS substrate 202. Suitable examples of such IC components may include, for example and without limitation, active components (e.g., transistors), passive components (e.g., capacitors, inductors, resistors, and the like), or combinations thereof.

The semiconductor device 200 of FIG. 2A further illustrates a plurality of electrically conductive lines or pads 208 disposed within a first dielectric layer or film 206 formed/deposited/patterned on the substrate 202. In some embodiments, the conductive pads 108 are implemented as Al—Cu pads. As depicted in FIG. 2A, the plurality of conductive lines or pads 208 are electrically coupled to respective conductive components 204 using one or more first electrically conductive vias 210. In accordance with one embodiment, the first vias 110 and the conductive pads 208 are formed from the same conductive material, i.e., AlCu. In other embodiments, the conductive material may comprise, for example and without limitation, a metal (e.g., titanium, tungsten, silver, gold, aluminum, copper, or alloys thereof), metal nitride, or any suitable combination thereof. In some embodiments, the pads 208 and the first vias 210 may be patterned simultaneously or sequentially. The conductive components 204, and/or conductive lines or pads 208 may be deposited by, for example, chemical vapor deposition (CVD), physical vapor deposition (PVD), atomic layer deposition (ALD), electroless plating, electrochemical plating, sputtering, ion metal plasma, another deposition process, or any suitable combination thereof. In some embodiments, the pads 108 may be exposed through the first dielectric layer 206, e.g., a top surface of the pads 108 is uncovered with respect to the first dielectric layer 206. In other embodiments, the top surface of the pad 208 may be covered by the first dielectric layer 206.

The first dielectric layer or film 206 may be deposited as a suitable dielectric material, such as an oxide, as will be appreciated by those skilled in the art. Suitable examples of the first dielectric layer 206 may include, for example and without limitation, an oxide (e.g., SiO₂), a nitride (e.g., SiN), an oxy-nitride (e.g., SiO_{X}N_{Y}), some other dielectric material, or any suitable combination thereof. The first dielectric layer 1206 may be deposited, for example and without limitation, by CVD, PVD, ALD, some other deposition process, or any suitable combination thereof. In accordance with one embodiment, the image depicted in FIG. 1A corresponds to redistribution layer formation and passivation processing of the semiconductor device 200, as will be understood by those skilled in the art.

FIG. 2B provides an illustration of the formation of electrically conductive sensing vias 216 during the production of the semiconductor device 200 in accordance with one embodiment. As shown in FIG. 2B, a second dielectric layer 212 and a third dielectric layer 214 are deposited on the semiconductor device 200. In some embodiments, the second dielectric layer 212 comprises a suitable nitride material, such as, for example and without limitation, a silicon nitride material. The third dielectric layer 214 may comprise, for example and without limitation, an oxide (e.g., SiO₂), a nitride (e.g., SiN), an oxy-nitride (e.g., SiO_{X}N_{Y}), some other dielectric material, or any suitable combination thereof. It will be appreciated that the first, second, and third dielectric layers 206, 212, and 214 may comprise three different dielectric materials, or two layers may be of the same dielectric material and the remaining layer may be of a different dielectric material, or all three dielectric layers 206, 212, and 214 may comprise the same dielectric material. The second and third dielectric layers 212 and 214, respectively, may be deposited by, for example and without limitation, CVD, PVD, ALD, some other deposition process, or a suitable combination thereof. In varying embodiments, each layer 212 and 214 may be deposited via different processes, in different process chambers, or using the same deposition process, as will be understood in the art. More generally, at least one bottom dielectric layer 212, 214 is deposited on top of the first dielectric layer 206 and the conductive lines or pads 208.

As shown in FIG. 2B, the plurality of sensing vias 216 are formed in the second and third dielectric layers 212, 214 (or, more generally, the at least one bottom dielectric layer 212, 214), passing into the first dielectric layer 206 contacting the conductive lines/pads 208. Suitable examples of such sensing vias 216 materials include, for example and without limitation, a metal (e.g., Al, Cu, AlCu, Ti, Ag, Au, W, or the like), a metal nitride (e.g., TiN), some other electrically conductive material, or any suitable combination thereof. It will be appreciated that the sensing vias 216 may be deposited by, for example and without limitation, CVD, PVD, ALD, electroless plating, electrochemical plating, sputtering, ion metal plasma, another deposition process, or any suitable combination thereof.

FIG. 2C illustrates the deposition of a bottom/sensing electrode 102 on the semiconductor device 200 in accordance with one embodiment. In the illustrative embodiment, the at least one sensing electrode 102 is a bottom electrode of a capacitive micromachined ultrasonic transducer unit. As shown in FIG. 2C, the bottom/sensing electrode 102 is patterned prior to the patterning (deposition and etching) of the dielectric films 220-224 (shown in FIG. 2H). The sensing electrode 102 is deposited on top of the at least one bottom dielectric layer 212, 214 (hence referring to the second and third dielectric layers 212, 214 as “bottom” dielectric layers). The sensing electrode 102 is patterned on the third dielectric layer 214 over the sensing vias 216 and in contact therewith. In accordance with varying embodiments contemplated herein, the sensing electrode 102 may comprise, for example and without limitation titanium (Ti) or other metal (e.g., Al, Cu, AlCu, Ag, Au, W, or the like), a metal nitride (e.g., titanium nitride (TiN), another conductive material, or suitable combinations thereof. The bottom/sensing electrode 102 may be deposited by, for example and without limitation, CVD, PVD, ALD, electroless plating, electrochemical plating, sputtering, ion metal plasma, another deposition process, or any suitable combination thereof.

As further shown in FIG. 2C, the bottom/sensing electrode 102 may comprise differing layers 120-122 of electrically conductive material, as will be appreciated. In FIG. 2C, the bottom/sensing electrode 102 comprises alternating layers of a first conductive material 120 deposited on the bottom dielectric layer(s) 206, 212, 214 and a second conductive material 122 deposited on the first conductive material 120. In accordance with one exemplary embodiment, the first conductive material 120 may comprise titanium (Ti, e.g., SPU-T) or other metal (e.g., Al, Cu, AlCu, Ag, Au, W, or the like) or other suitable material, as will be appreciated by those skilled in the art. In such an exemplary embodiment, the second conductive material 122 may comprise a metal nitride (e.g., titanium nitride (TiN) or other suitable material, as will be appreciated by the skilled artisan. Moreover, while the illustrative bottom/sensing electrode 102 comprises multiple layers 120-122 of conductive material, it is contemplated for the bottom/sensing electrode to comprise a single layer of electrically conductive material.

FIG. 2D illustrates a deposition of a pedestal dielectric film 104 for formation of one or more pedestals 106 in accordance with one exemplary embodiment. As shown in FIG. 2D, the pedestal dielectric film 104 is deposited on the layers 120-122 of the bottom/sensing electrode 102. In some exemplary embodiments, the pedestal dielectric film 104 may comprise an oxide (e.g., SiO₂), a nitride (e.g., SiN), an oxy-nitride (e.g., SiO_{X}N_{Y}), some other dielectric material, or any suitable combination thereof. It will be appreciated by those skilled in the art that the pedestal dielectric layer 104 may be deposited, for example and without limitation, by CVD, PVD, ALD, some other deposition process, or any suitable combination thereof.

FIG. 2E depicts the initial patterning/etching of pedestals 106 in the pedestal dielectric layer 104 in accordance with one exemplary embodiment. The patterning may, for example, employ photolithographic patterning using a photoresist layer deposition/exposure/development/etching sequence. As shown in FIG. 2E, the exemplary patterning forms a portion of the pedestals 106 located on the bottom/sensing electrode 102. In accordance with one embodiment, this initial patterning of the pedestals 106 occurs in a predetermined pattern of pedestals 106 within the landing area 112 on the bottom/sensing electrode 102, e.g., as shown in FIGS. 1A-1B.

FIG. 2F illustrates the patterning of the sensing/bottom electrode 102 in accordance with a pattern first methodology utilized herein. The illustrative patterning of FIG. 2F forms an illustrative isolation trench 226 passing through the pedestal dielectric layer 104 and the sensing/bottom electrode 102. The isolation trench 226 may, for example, encircle the landing area 112 discussed previously with reference to FIG. 1B, to electrically isolate the portion of the sensing/bottom electrode layer 102 within the landing area 112.

As shown in FIG. 2G, a fifth dielectric film 220 is deposited on the already deposited pedestal dielectric film 104 on the patterned bottom/sensing electrode 102. A sixth dielectric film 222 is then deposited on the fifth dielectric film 220. It will be appreciated by those skilled in the art that the composition of the dielectric layers 220, and 222 may be deposited, for example and without limitation, by CVD, PVD, ALD, some other deposition process, or any suitable combination thereof. In the illustrative example of FIG. 2G, the fifth dielectric film 220 comprises the same material as that of the pedestal dielectric film 104, e.g., a suitable oxide (e.g., SiO₂), a nitride (e.g., SiN), an oxy-nitride (e.g., SiO_{X}N_{Y}), some other dielectric material, or any suitable combination thereof. In such an example, the sixth dielectric film 222 comprises a different dielectric material, i.e., when the pedestal dielectric film 104 and fifth dielectric film 104 are a suitable oxide, then the sixth dielectric film 222 comprises a suitable nitride material. Also illustrated in FIG. 2G is the isolation trench 226, located adjacent the bottom/sensing electrode 102 and filled with the fifth and sixth dielectric layers 220-222. The skilled artisan will appreciate that the isolation trench 226 provides protection from electric current leakage between the various conductive components, i.e., the bottom/sensing electrode 102, in accordance with one embodiment contemplated herein. As further seen in FIG. 2G, the dielectric films 220 and 222 coat the patterned portions of the pedestal dielectric film 104 to enlarge the pedestals 106. While two dielectric films 220 and 222 are illustrated in FIG. 2G, it is contemplated to have as few as a single dielectric film or, conversely, to have three or more dielectric films, deposited in this step. In yet other contemplated embodiments, the step of FIG. 2G may be omitted entirely.

FIG. 2H illustrates the deposition and subsequent chemical mechanical planarization (“CMP”) of a top (seventh) dielectric film 224 on the sixth dielectric film 222 and the fifth dielectric film 220. As will be appreciated by those skilled in the art, the deposition of the top (seventh) dielectric film 224 results in an uneven surface of the semiconductor device 200, for example with a depression or valley at the surface corresponding to the trench 226. As depicted in FIG. 2H, the semiconductor device 200 (and more particularly the deposited seventh dielectric film 224) has been subjected to suitable planarization, i.e., polishing, to remove excess material from the seventh dielectric film 224. It will be appreciated that the isolation trench 226 located adjacent the bottom/sensing electrode 102 is suitably filled with the material of the seventh dielectric film 224. The skilled artisan will appreciate that the CMP may be performed to remove a portion of the seventh dielectric film 224 in preparation for additional patterning. The resulting planarization of the semiconductor device 200 from the CMP process is accordingly depicted in FIG. 2H. As can be seen in FIG. 2H, the pedestals 106 are at this stage in the process buried by the seventh dielectric layer 224.

Turning now to FIG. 2I, there is shown an illustration of the patterning of a cavity 228 on the semiconductor device 200 in accordance with one embodiment. The cavity 228 may be, for example, the cavity of the CMUT device. Notably, this patterning removes the planarized seventh dielectric film 224 to define the cavity 228, and in so doing the underlying pedestals 106 are exposed. The pedestals 106 at the fabrication stage shown in FIG. 2I include the portions of the patterned dielectric layer 104 defined by the patterning step shown in FIG. 2E coated by the dielectric layer 220 previously deposited as shown in FIG. 2G. More particularly, as shown in FIG. 2I, a portion of the seventh and sixth dielectric films 222 and 224 deposited in FIG. 2G and subsequently planarized in FIG. 2H is removed (i.e., patterned, etched, etc.) from the semiconductor device 200 to expose the isolation trench 226 and the pedestals 106 formed on the bottom/sensing electrode 102. In this manner, a cavity 228 is formed in the sixth and seventh dielectric layers 222, 224 and over the bottom/sensing electrode 102 as shown in FIG. 2I.

Alternatively, in some embodiments, a process for forming the cavity 228 comprises forming a patterned masking layer (not shown) (e.g., positive/negative photoresist, hardmask, etc.) over the seventh dielectric layer 224, over the bottom/sensing electrode 102, the pedestals 106, and the trench 226. Thereafter, an etching process is performed to remove unmasked portions of the seventh dielectric layer 224 exposing the sixth dielectric layer 222. The masking layer may be removed and then a second masking layer is patterned to enable removal of a portion of the sixth dielectric layer 222 from a portion of the trenches 226 and above the pedestals 106 on the bottom/sensing electrode 102, thereby forming the cavity 228. The etching process may be a dry etching process, a RIE process, a wet etching process, some other etching process, or a combination of the foregoing. Subsequently, in some embodiments, the patterned masking layer is stripped away.

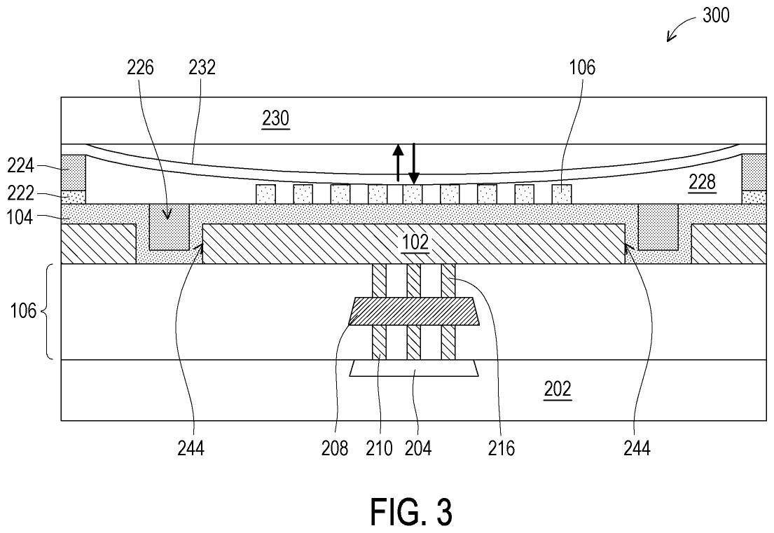

Alternatively, in some embodiments, a single masking and etching process may be used, to remove portions of the seventh dielectric layer 224 and sixth dielectric layer 222 over the trenches 226, pedestals 106, and bottom/sensing electrode 102. As illustrated in FIG. 2I, the fifth dielectric layer 220 suitably remains over the pedestal dielectric layer 104 and bottom/sensing electrodes 102 and lines the isolation trenches 226. Further, a portion of the sixth dielectric layer 222 and the seventh dielectric layer 224 remains in the isolation trenches 226, as more clearly illustrated in FIG. 3, discussed below.

FIG. 2J illustrates a side view of the bonding of the semiconductor device 200 with a corresponding carrier wafer 230 in accordance with one embodiment. As shown in FIG. 2J, the carrier wafer 230 encloses the pedestals 106 and bottom/sensing electrode 102 within the cavity 228. In some embodiments, the carrier wafer 230 includes a membrane (not shown) that facilitates operation of the semiconductor device 200 (e.g., the membrane is the portion of the CMUT device that oscillates in response to an acoustic wave thereby producing a variable capacitance between the bottom electrode 102 and a top electrode disposed on the membrane to produce an electrical signal; or conversely, the membrane is electrically energized with an AC signal to induce oscillation of the membrane to generate an acoustic wave). In some embodiments, the membrane is designed to contact the landing area 112 on each oscillation, thus providing a binary (i.e., digital) CMUT output. Other approaches for forming a suitable CMUT membrane with a top electrode over the cavity 228 are also contemplated, such as by sacrificial release surface micromachining techniques which do not employ wafer bonding.

Turning now to FIG. 3, there is shown a CMUT unit 300 utilizing pedestals 106 in accordance with some embodiments. As illustrated in FIG. 3, the CMUT unit 300 includes a membrane 232 illustrated as distinct from the carrier wafer 230 for example purposes. According to some embodiments, the membrane 232 is configured to move or clap (e.g., flex, vibrate, etc.) in response to one or more stimuli (e.g., acoustic pressure wave, applied voltage, etc.). The detailed view in FIG. 3 illustrates the presence of the dielectric layers 104, 222, 224 in the isolation trench 226 and adjacent to the side of the bottom/sensing electrode 102, as well as a plurality of pedestals 106 formed of dielectric material 104, 220 on the top of the bottom/sensing electrode 102.

During operation of the CMUT unit 300, the membrane 232 may clap in response to the aforementioned stimuli. When this occurs, the membrane 232 contacts the pedestals 106 of dielectric material 104, 220 disposed over the bottom/sensing electrode 102. The pedestals 106 advantageously reduce the contact area during the clap event, thus reducing the likelihood (or at least the magnitude) of stiction. In some embodiments, the pedestals may be configured to increase the separation of the top and bottom electrodes during a clap event, thus reducing the electric field and accumulated electric charge. As shown in FIG. 3, the sidewalls 244 of the bottom/sensing electrode 102 are protected by the presence of the fifth, sixth and seventh dielectric layers 220-224 (i.e., in the isolation trench 226) in accordance with the “patterning first” of the bottom/sensing electrode 102 as discussed above with respect to FIGS. 2A-2J. In the absence of this protection, once the bottom/sensing electrode 102 is no longer highly protected by the dielectric films 220-224, charging can accumulate at the corner/sidewall of the bottom/sensing electrode 102, resulting in failure of the CMUT unit 300.

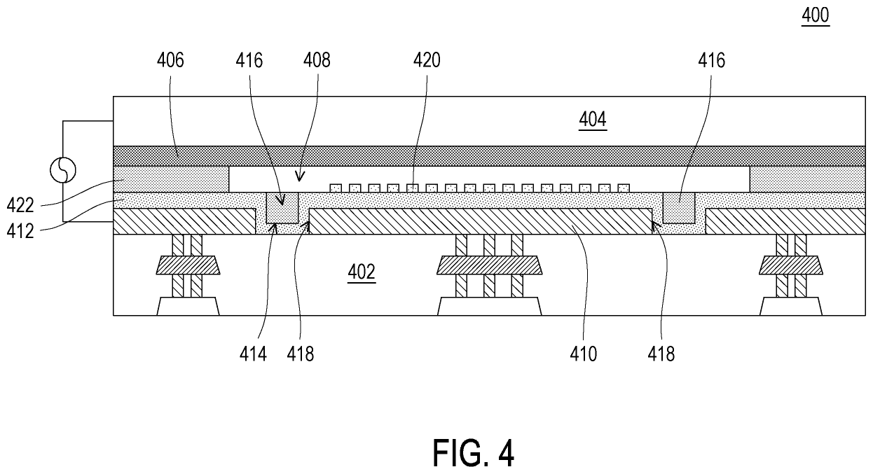

Referring now to FIG. 4, there is shown a simplified side view of a CMUT unit 400 utilizing one or more dielectric pedestals 420 produced in accordance with the bottom/sensing electrode 102 “patterning first” and pedestal 106 formation process as discussed above in FIGS. 2A-2J. As shown in FIG. 4, the CMUT unit 400 includes a device substrate 402 and a membrane 404 bonded together via a bonding surface 406. The skilled artisan will appreciate that the CMUT unit 400 illustrated in FIG. 4, the membrane 404 is implemented as a carrier wafer, e.g., a silicon membrane. A cavity 408 is formed between the bonded substrate 402 and membrane 404, in which is disposed a bottom/sensing electrode 410. Present at either end of the cavity 408 shown in FIG. 4 are cavity dielectric components 422, which may be implemented as a suitable dielectric material, e.g., an oxide material. A dielectric film 412 is located on the top and sidewalls 418 of the bottom/sensing electrode 410. Surrounding the bottom/sensing electrode 410 is an isolation trench 414 having the dielectric film 412 disposed therein. The isolation trench 414 further includes a dielectric material 416 filling the trench 414 and deposited adjacent the dielectric film 412. Formed from the dielectric film 412 are one or more pedestals 420 positioned in on the top of the bottom/sensing electrode 420.

In accordance with some embodiments, the one or more pedestals 420 each includes a pedestal diameter (“P”) and a pedestal height (“H”), thereby defining an aspect ratio of “H/P”. In some embodiments, the aspect ratio H/P may range from 0.025~0.2, e.g., H=0.1 micrometers and P=4 micrometers to H=0.1 micrometers and P=0.5 micrometers. It will be appreciated that the pedestal 420 may have a cylindrical profile for exemplary purposes only, and other profiles are equally contemplated herein, for example and without limitation, rectangular, polygonal, elliptical, button, ball, and the like. In such an embodiment, the one or more pedestals 420 are arranged within a landing area of the dielectric film 412. It will be appreciated that the landing area corresponds to the surface area of the bottom/sensing electrode 410 that contacts (or has a high likelihood of contacting) a movable membrane 404 during operations of the CMUT device 400. In accordance with some exemplary embodiments, the landing area may correspond to greater than or equal to 60% of the bottom/sensing electrode area, and a single pedestal 420 may define greater than or equal to 1.5% of such a landing area. The pattern of the pedestals 420 formed of the dielectric layer 412 may utilize a predetermined pedestal-to-pedestal spacing corresponding to the spacing of pedestals 420 within the landing area. A pedestal-to-pedestal pitch ratio (“S”) can also be defined as a ratio of the pedestal diameter (or other principal pedestal dimension) to the pedestal-to-pedestal spacing. In some embodiments, the pitch ratio S may be in the range of less than or equal to 80%, so as to minimize charging accumulation on the bottom/sensing electrode 410 during operations of the CMUT device 400.

The dielectric film 412 deposited on the bottom/sensing electrode 410 is configured to prevent charging of the membrane 404 during operations of the CMUT unit 400. To facilitate this protection, as indicated above with respect to FIGS. 1A-3, the bottom/sensing electrode 410 is patterned first, after which the dielectric film 412 and one or more pedestals 420 are patterned. The aforementioned charging may occur along a side wall 418 of the bottom/sensing electrode 410, which is alleviated in embodiments disclosed herein. Further, the placement of the one or more pedestals 420 below the membrane 404 alleviate the aforementioned degradation of the membrane 404 and prolong the life of the CMUT unit 400 by minimizing the amount of contact the membrane 404 has with the dielectric film 412 during CMUT operations.

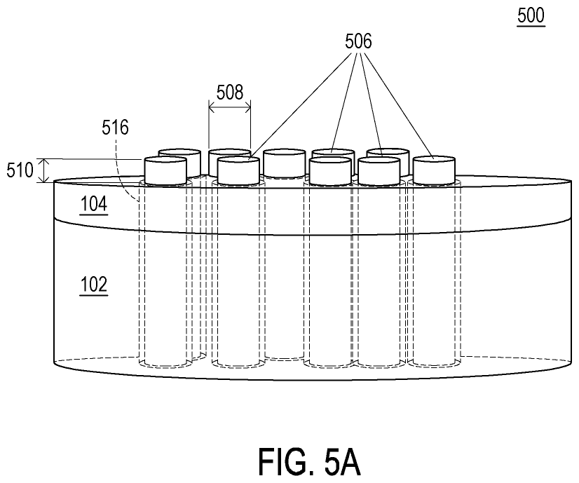

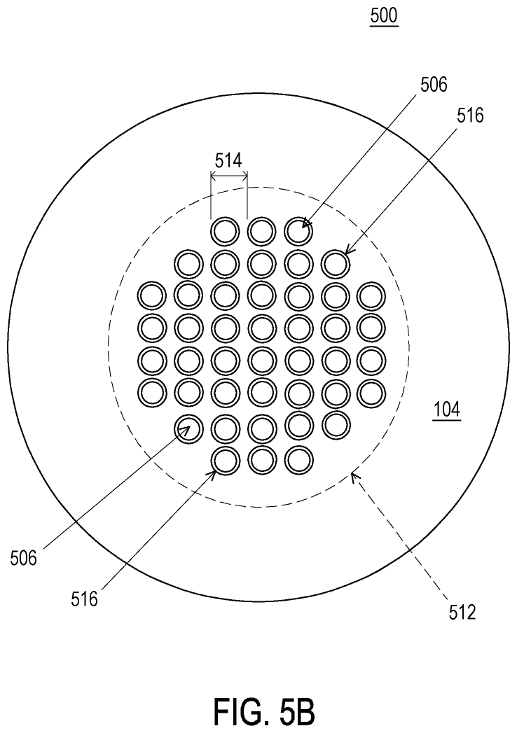

Turning now to FIGS. 5A-5B, there is shown a simplified side view of a bottom/sensing electrode component 500 utilized in a CMUT device (FIG. 5A) and a simplified top view of the bottom/sensing electrode component 500 (FIG. 5B) utilizing one or more isolation pedestals 506 in accordance with some embodiments disclosed herein. As illustrated in FIG. 5A, the bottom/sensing electrode component 500 is depicted comprising a bottom/sensing electrode 102, a pedestal dielectric layer 104 and one or more isolation pedestals 506, disposed on the pedestal dielectric layer 104. In accordance with some embodiments, each isolation pedestal 506 includes a pedestal diameter (“P”) 508 and a pedestal height (“H”) 510 (above the bottom/sensing electrode 102), thereby defining an aspect ratio of “H/P”. In some embodiments, the aspect ratio H/P may range from 0.025~0.2, e.g., H=0.1 micrometers and P=4 micrometers to H=0.1 micrometers and P=0.5 micrometers. Each isolation pedestal 506 is positioned within an isolation cavity 516 surrounding the isolation pedestal 506, thereby isolating the pedestal 506 and material of the bottom/sensing electrode 102 from each adjacent isolation pedestal 506. That is, each isolation pedestal 506 and a corresponding portion of the bottom/sensing electrode 102 material is positioned within the isolation cavity 516. It will be appreciated that such usage of isolation cavities 516 may provide additional charging prevention regarding the bottom/sensing electrode 102. It will also be appreciated that the isolation pedestal 506 is depicted as having a cylindrical profile for exemplary purposes only, and other profiles are equally contemplated herein, for example and without limitation, rectangular, polygonal, elliptical, button, ball, and the like. In such embodiments, the skilled artisan will appreciate that the aforementioned isolation cavity 516 mirrors the shape of the isolation pedestal 506, ensuring that the isolation pedestal 506 positioned within the isolation cavity 516 is suitably isolated/insulated from adjacent pedestals 506. The previously mentioned isolation is more readily discernible in FIG. 5B.

As shown in FIG. 5B, the one or more isolation pedestals 506 are arranged within a landing area 512 of the pedestal dielectric layer 104. It will be appreciated that the landing area 512 corresponds to the surface area of the bottom/sensing electrode component 500 that contacts a movable membrane (not shown) during operations of the CMUT device. In accordance with some exemplary embodiments, the landing area 512 may correspond to greater than or equal to 60% of the bottom/sensing electrode area, and a single isolation pedestal 506 may define greater than or equal to 1.5% of such a landing area 512. Also shown in FIG. 5B, the pattern of the isolation pedestals 506 formed of the first electric layer 104 utilizes a predetermined pedestal-to-pedestal spacing corresponding to the spacing of isolation pedestals 506 within the landing area. A pedestal-to-pedestal pitch ratio (“S”) can also be defined as a ratio of the pedestal diameter 508 (or other principal pedestal dimension) to the pedestal-to-pedestal spacing. In some embodiments, the pitch ratio S may be in the range of less than or equal to 80%, so as to minimize charging accumulation on the bottom/sensing electrode 102 during operations of the CMUT device. The formation of a semiconductor device 500 utilizing the dielectric pedestal design depicted in FIGS. 5A-5B is illustrated in greater detail above with respect to FIGS. 2A-2J. It will be appreciated, however, that the patterning and etching of the isolation pedestals 506 may further include patterning and etching of the bottom/sensing electrode 102, whereby the isolation cavities 516 are formed therebetween.

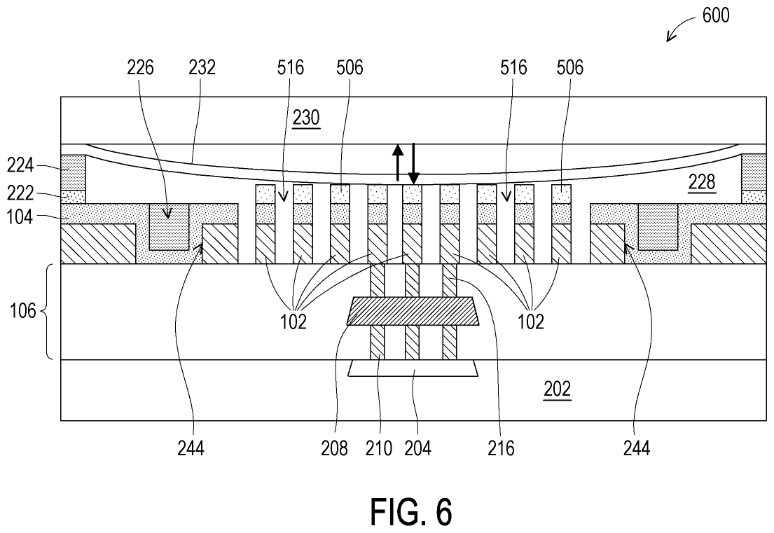

Turning now to FIG. 6, there is shown a CMUT unit 600 utilizing isolation pedestals 506 in accordance with some embodiment. As illustrated in FIG. 6, the CMUT unit 600 includes a membrane 232 illustrated as distinct from the carrier wafer 230 for example purposes. According to some embodiments, the membrane 232 is configured to clap in response to one or more stimuli (e.g., pressure, voltage, etc.) of sufficient magnitude. The detailed view in FIG. 6 illustrates the presence of the dielectric layers 104, 222, 224, i.e., the isolation trench 226, and adjacent to the side of the bottom/sensing electrode 502, as well as a plurality of isolation pedestals 506 formed of dielectric material 104, 220 on the top of the bottom/sensing electrode 102. Each isolation pedestal 506 may be encapsulated within an isolation cavity 516, wherein each pedestal 506 and underlying portion of the bottom/sensing electrode 102 material is separated (e.g., insulated, distinct, etc.) from adjacent pedestals 506 within the aforementioned landing area 512, as shown in FIGS. 5A-5B. The skilled artisan will appreciate that the use of such isolation cavities 516 may provide additional charging prevention regarding the bottom/sensing electrode 102.

During operation of the CMUT unit 600, the membrane 232 claps in response to the aforementioned stimuli. When this occurs, the membrane 232 contacts the isolation pedestals 506 of dielectric material 104, 220 disposed over the bottom/sensing electrode 102, providing a reduced contact area compared with a design that omits the pedestals 506. As shown in FIG. 6, the sidewalls 244 of the bottom/sensing electrode 102 are highly protected by the presence of the fifth, sixth and seventh dielectric layers 220-224 (i.e., in the isolation trench 226) in accordance with the “patterning first” of the bottom/sensing electrode 102 as discussed above with respect to FIGS. 2A-2J. In the absence of this protection, once the bottom/sensing electrode 102 is no longer highly protected by the dielectric films 220-224, charging can accumulate at the corner/sidewall of the bottom/sensing electrode 102, resulting in failure of the CMUT unit 600.

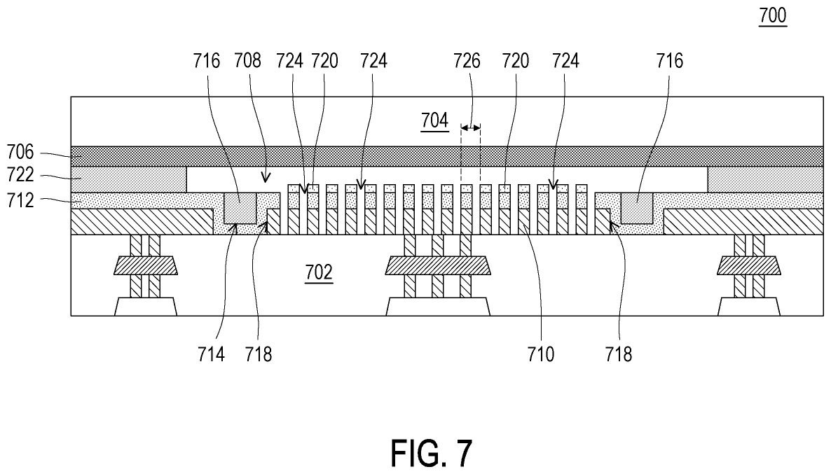

Referring now to FIG. 7, there is shown a simplified side view of a CMUT unit 700 utilizing one or more isolated dielectric pedestals 720 produced in accordance with the bottom/sensing electrode “patterning first” and pedestal formation process as discussed above in FIGS. 2A-2J. It will be appreciated that in addition to the process illustrated in FIGS. 2A-2J, formation of the isolation cavities 724, which extend from the surface of the dielectric film 712 (discussed below) to the substrate 702 is also patterned and etched to form the isolation pedestals 720 and corresponding bottom/sensing electrode 710 component, as illustrated in FIG. 7. As shown in FIG. 7, the CMUT unit 700 includes a device substrate 702 and a membrane 704 bonded together via a bonding surface 706. The skilled artisan will appreciate that the CMUT unit 700 illustrated in FIG. 7, the membrane 704 is implemented as a carrier wafer, e.g., a silicon membrane.

A cavity 708 is formed between the bonded substrate 702 and membrane 704, in which is disposed a bottom/sensing electrode 710. Present at either end of the cavity 708 shown in FIG. 7 are cavity dielectric components 722, which may be implemented as a suitable dielectric material, e.g., an oxide material. A dielectric film 712 is located on the top and sidewalls 718 of the bottom/sensing electrode 710. Surrounding the bottom/sensing electrode 710 is an isolation trench 714 having the dielectric film 712 disposed therein. The isolation trench 714 further includes a dielectric material 716 filling the trench 714 and deposited adjacent the dielectric film 712. Formed from the dielectric film 712 are one or more pedestals 720 positioned in on the top of the bottom/sensing electrode 720. As shown in FIG. 7, each of the one or more pedestals 720 is positioned within an isolation cavity 724, devoid of material, including the bottom/sensing electrode 710. It will be appreciated that such usage of isolation cavities 724 may provide additional charging prevention, as well as reduce the surface area (i.e., landing area) contacting the membrane 704 during operations of the CMUT unit 700.

In accordance with some embodiments, the one or more pedestals 720 each includes a pedestal diameter (“P”) and a pedestal height (“H”), thereby defining an aspect ratio of “H/P”. In some embodiments, the aspect ratio H/P may range from 0.025~0.2, e.g., H=0.1 micrometers and P=4 micrometers to H=0.1 micrometers and P=0.5 micrometers. It will be appreciated that the pedestal 720 is depicted as having a cylindrical profile for exemplary purposes only, and other profiles are equally contemplated herein, for example and without limitation, rectangular, polygonal, elliptical, button, ball, and the like.

In such an embodiment, the one or more pedestals 720 are arranged within a landing area of the dielectric film 712. Further, in such embodiments, the corresponding isolation cavities 724 will generally mirror the shape of the pedestals 720, e.g., when the pedestal 720 is cylindrical, the corresponding isolation cavity 724 is cylindrical, when the pedestal 720 is rectangular, the corresponding isolation cavity 724 is rectangular, and the like. It will be appreciated that the landing area corresponds to the surface area of the bottom/sensing electrode 710 that contacts a movable membrane 704 during operations of the CMUT device 700. In accordance with some exemplary embodiments, the landing area may correspond to greater than or equal to 60% of the bottom/sensing electrode area, and a single pedestal 720 may define greater than or equal to 1.5% of such a landing area. The pattern of the pedestals 720 formed of the dielectric layer 712 may utilize a predetermined pedestal-to-pedestal spacing 726 corresponding to the spacing of pedestals 720 within the landing area. A pedestal-to-pedestal pitch ratio (“S”) can also be defined as a ratio of the diameter of a pedestal 720 (or other principal pedestal dimension) to the pedestal-to-pedestal spacing 114. In some embodiments, the pitch ratio S may be in the range of less than or equal to 80%, so as to minimize charging accumulation on the bottom/sensing electrode 710 during operations of the CMUT device 700.

The dielectric film 712 deposited on the bottom/sensing electrode 710 is configured to prevent charging of the membrane 704 during operations of the CMUT unit 700. To facilitate this protection, as indicated above with respect to FIGS. 1A-3, the bottom/sensing electrode 710 is patterned first, after which the dielectric film 712 and one or more pedestals 720 are patterned. The aforementioned charging may occur along a side wall 718 of the bottom/sensing electrode 710, which is alleviated in embodiments disclosed herein. Further, the placement of the one or more pedestals 720 below the membrane 704 alleviate the aforementioned degradation of the membrane 704 and prolong the life of the CMUT unit 700 by minimizing the amount of contact the membrane 704 has with the dielectric film 712 during CMUT operations. Other embodiments contemplated herein utilize a mixture of isolation pedestals 506 and pedestals 106 within the landing area 112/512, as will be appreciated by the skilled artisan.

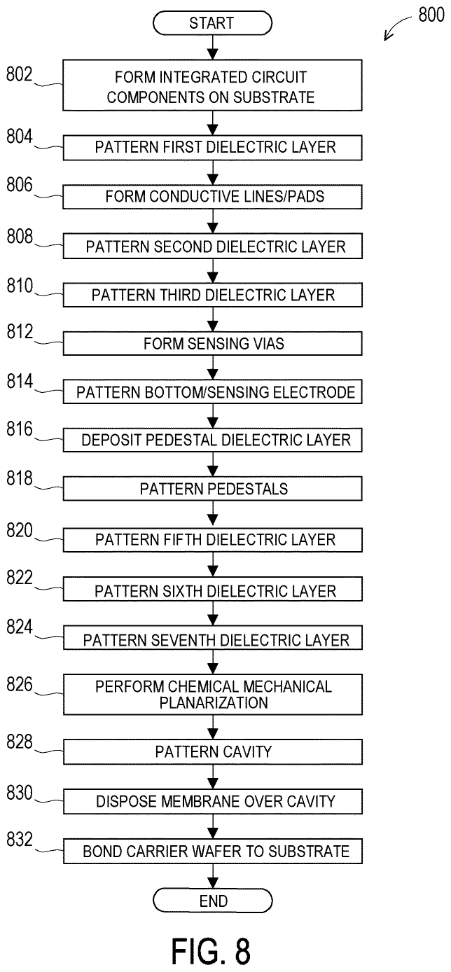

Turning now to FIG. 8, there is shown a flow chart illustrating a method 800 for bottom/sensing electrode patterning first fabrication of a CMUT MEMS device in accordance with one embodiment. The method 800 begins at step 802, whereupon one or more integrated circuit components 204 are formed on a CMOS substrate 202. It will be appreciated by those skilled in the art that the integrated circuit components 204 may be or comprise, for example and without, active electronic devices (e.g., transistors), passive electronic devices (e.g., resistors, capacitors, inductors, fuses, etc.), some other electronic devices, or a combination thereof. Formation of these integrated circuit components 204 may be accomplished in accordance with suitable deposition, etching, etc., processes as will be appreciated by those skilled in the art.

At step 804, a first dielectric layer 206 is formed on the substrate 202. In some embodiments, the first dielectric layer 206 may be a dielectric oxide (e.g., SiO₂), a nitride (e.g., SiN), an oxy-nitride (e.g., SiO_{X}N_{Y}), some other dielectric material, or any suitable combination thereof. The first dielectric layer 206 may be deposited, for example and without limitation, by CVD, PVD, ALD, some other deposition process, or any suitable combination thereof.

At step 806, a plurality of conductive lines or pads 208 and first vias 210 are formed on the substrate 202. In accordance with one embodiment, the first vias 210 and the conductive pads 208 are formed from the same conductive material, i.e., AlCu. In other embodiments, the conductive material may comprise, for example and without limitation, a metal (e.g., titanium, tungsten, silver, gold, aluminum, copper, or alloys thereof), metal nitride, or any suitable combination thereof. In some embodiments, the pads 208 and the first vias 210 may be patterned simultaneously or sequentially. The conductive components 204, and/or conductive lines or pads 208 may be deposited by, for example, CVD, PVD, ALD, electroless plating, electrochemical plating, sputtering, ion metal plasma, another deposition process, or any suitable combination thereof. These two steps are illustrated in FIG. 2A.

At step 808, a second dielectric layer 212 is deposited on the first dielectric layer 206. In some embodiments, the second dielectric layer 212 comprises a suitable nitride material, such as, for example and without limitation, a silicon nitride material.

At step 810, a third dielectric layer 214 is deposited on the second dielectric layer 212. The third dielectric layer 214 may comprise, for example and without limitation, an oxide (e.g., SiO₂), a nitride (e.g., SiN), an oxy-nitride (e.g., SiO_{X}N_{Y}), some other dielectric material, or any suitable combination thereof.

At step 812, a plurality of sensing vias 216 are formed on the conductive lines/pads 208, through the second and third dielectric layers 212, 214. In some embodiments, a patterned masking layer (e.g., positive/negative photoresist, hardmask, etc.) may be layered over the third dielectric layer 214, patterning mask. In further embodiments, the patterned masking layer may be formed by forming a masking layer on the third dielectric layer 214, exposing the masking layer to a pattern (e.g., via a lithography process, such as photolithography, extreme ultraviolet lithography, or the like), and developing the masking layer to form the patterned masking layer. Thereafter, an etching process is performed to remove unmasked portions of the third dielectric layer 214 and the second dielectric layer 212, thereby forming openings therethrough over the conductive pads/lines 208. The aforementioned etching process may be a dry etching process, a wet etching process, a reactive ion etching (RIE) process, some other etching process, or a combination of the foregoing. The sensing vias 216 may then be deposited via any suitable means and the aforementioned patterned masking layer is stripped away.

In accordance with another embodiment, steps 808, 810, 812 may be performed in an alternate manner, wherein the material for the sensing vias 216 is deposited first, then a patterning mask is formed protecting the desired sensing vias 216, followed by etching to remove the undesired sensing via material. Thereafter, deposition of the second and third dielectric layers 212, 214, may be performed as discussed above. The photoresist protecting the sensing vias 216 is then removed resulting in the image provided in FIG. 2B.

After formation of the sensing vias 216, operations proceed to step 814, whereupon bottom/sensing electrodes 102 are patterned on the second dielectric layer 214 and in contact with the sensing vias 216. That is, a patterned masking layer (i.e., positive/negative photoresist, hardmask, etc.) is formed over the third dielectric layer 214. The bottom/sensing electrodes 102 are then deposited via photoresist or other masking component is deposited by, for example and without limitation, CVD, PVD, ALD, electroless plating, electrochemical plating, sputtering, ion metal plasma, another deposition process, or any suitable combination thereof. According to one embodiment, the bottom/sensing electrode 102 may comprise alternating layers of titanium 120 and titanium nitride 122. In some embodiments, the bottom/sensing electrode 102 may comprise titanium deposited via ion metal plasma deposition at a thickness in the range of 80 to 110 angstroms. According to another embodiment, the bottom/sensing electrode 102 may comprise titanium deposited via sputtering deposition at a thickness in the range of 15 to 40 angstroms. In other embodiments, the bottom/sensing electrode 102 may comprise, for example and without limitation, Al, Cu, AlCu, Ag, Au, W, or the like, a metal nitride (e.g., TiN), or other conductive material. Subsequently, in some embodiments, the patterned masking layer is stripped away, resulting in the patterned first bottom/sensing electrodes 102 as illustrated in FIG. 2C.

At step 816, a fourth dielectric layer, i.e., the pedestal dielectric layer/film 104 i deposited on the third dielectric layer 214 and bottom/sensing electrodes 102. In accordance with one embodiment, the pedestal dielectric layer 104 comprises an oxide material that is deposited via chemical vapor deposition (CVD). In other embodiments, the oxide material may be deposited via atomic layered deposition (ALD), or the like. An illustration of the deposition of the pedestal dielectric layer 104 is provided in FIG. 2D, discussed in greater detail above.

At step 818, one or more pedestals 106 are patterned in the pedestal dielectric layer 104. In accordance with one embodiment, the one or more pedestals 106 are patterned within a predetermined area on the top surface of the bottom/sensing electrode 102, e.g., the landing area 112 as illustrated in FIGS. 1A-1B and/or landing area 512 illustrated in FIGS. 5A-5B. In some embodiments, one or more isolation trenches 226 are etched into the bottom/sensing electrode 102, as illustrated in FIG. 2F.

A fifth dielectric layer or film 220 is then deposited over the pedestal dielectric layer 104 and pedestals 106 at step 820. In accordance with one exemplary embodiment, the fifth dielectric layer 220 comprises an oxide or nitride material. In accordance with one exemplary embodiment, the fifth dielectric film 220 comprises the same material as that of the pedestal dielectric film 104, e.g., a suitable oxide (e.g., SiO₂), a nitride (e.g., SiN), an oxy-nitride (e.g., SiO_{X}N_{Y}), some other dielectric material, or any suitable combination thereof.

At step 822, a sixth dielectric layer 222 is deposited on the fifth dielectric layer 220. According to one exemplary embodiment, the sixth dielectric layer 220 comprises an oxide material, e.g., SiO2 or the like. FIG. 2G provides an illustrative example of the semiconductor device 200 after completion of steps 816, 818, 820, and 822.

A seventh dielectric layer 224 is then deposited on the sixth dielectric layer 222 at step 824. In accordance with some embodiments, the seventh dielectric layer 224 comprises a suitable dielectric material, e.g., a suitable oxide (e.g., SiO₂), a nitride (e.g., SiN), an oxy-nitride (e.g., SiO_{X}N_{Y}), some other dielectric material, or any suitable combination thereof. In various embodiments, the seventh dielectric layer 224 comprises a different material than the sixth dielectric layer/film 222, which may be deposited via high-density plasma (HDP) CVD. It will be appreciated that the deposition of the seventh dielectric layer 224 results in an uneven surface of the semiconductor device 200. Accordingly, operations for the fabrication of the semiconductor device 200 then proceed to step 826, whereupon chemical mechanical planarization (CMP) is performed so as to remove excess portions of the seventh dielectric layer 224, as illustrated in FIG. 2H.

At step 828, cavities 228 are formed over the bottom/sensing electrodes 102, pedestals 106, and isolation trenches 226. That is, a patterned masking layer (e.g., positive/negative photoresist, hardmask, etc.) may be formed over the seventh dielectric layer 224, leaving exposed the seventh dielectric layer 224 over the bottom/sensing electrodes 102, the pedestals 106, and the trenches 226. Thereafter, an etching process is performed to remove portions of the unmasked seventh dielectric layer 224 and the sixth dielectric layer 222, thereby forming the cavities 228 and exposing the pedestals 106 and trenches 226. The etching process may be a dry etching process, a RIE process, a wet etching process, some other etching process, or a combination of the foregoing. Thereafter, the patterned masking layer is stripped away. The result is shown in FIG. 2I.

In some embodiments, a second masking and etching process may be used, i.e., when the sixth dielectric layer 222 remains after the first masking/etching process to remove portions of the seventh dielectric layer 224 over the trenches 226, pedestals 106, and bottom/sensing electrodes 102. As illustrated in FIG. 2I, the fifth dielectric layer 220 suitably remains over the bottom/sensing electrodes 102 (and pedestals 106) and lines the isolation trenches 226. Accordingly, the skilled artisan will appreciate that one or more masks and etching processes may be used to form the cavities 228 of the semiconductor device 200.

It will further be appreciated that the thickness of the fifth dielectric layer 220 lining the bottom/electrode 102 wall 244 may be dependent upon the surface roughness of the bottom/electrode 102. Thus, for example and without limitation, when the bottom/sensing electrode 102 comprises titanium that is deposited via ion metal plasma, the fifth dielectric film 220 may have a thickness L in the range of 150 to 300 angstroms, and may be greater than 200 angstroms thick. In another example, using titanium as the bottom/sensing electrode 102 deposited via sputtering, the fifth dielectric film 220 may have a thickness L in the range of 50 to 80 angstroms, and may be greater than 60 angstroms thick.

At step 830, a movable membrane 232 is disposed over the cavity 228. At step 832, the CMUT semiconductor device 200 is formed by bonding of the integrated circuit substrate 202 to a carrier wafer 230. In some embodiments, steps 830 and 832 are combined, wherein the membrane 232 is a component of the carrier wafer 230, such that bonding of the carrier wafer 230 with the integrated circuit substrate 202 disposes the movable membrane 232 over the cavity 228. In accordance with some embodiments, the semiconductor device 200 may be bonded to the carrier wafer 230 using a fusion bonding process. The skilled artisan will appreciate that other types of bonding processes may be used to join the semiconductor device 200 with the carrier wafer 230, including for example and without limitation, eutectic bonding, or the like. The result is shown in FIG. 2J.

In accordance with another embodiment, the patterning of the cavities 228 at step 828 may further include patterning the isolation cavities 516 surrounding isolation pedestals 506, as illustrated in FIGS. 5A-7. In such an embodiment, the masking and etching procedures discussed above may be used to remove portions of the top dielectric layers (dielectric films 104, 220, 222, and 224) as well as portions of the bottom/sensing electrode 102, thereby forming the isolation pedestals depicted in FIGS. 5A-7.

The illustrative embodiments have been described in conjunction with a “patterning-first” fabrication approach in which (with illustrative reference back to FIG. 3) the isolation trench 226 is patterned first (e.g., FIG. 2F) followed by deposition of dielectric layer(s) 220-224 (e.g., FIG. 2G), so that the sidewalls 244 of the bottom/sensing electrode 102 are protected by the dielectric layer(s) 220-224. However, it will be appreciated that the disclosed approach of employing pedestals to reduce the contact area of the membrane during clap events so as to reduce or eliminate stiction and potentially reduce accumulated charge can be employed in conjunction with substantially any type of CMUT device, including CMUT devices fabricated using approaches other than the “patterning-first” approach. The pedestals can be formed in the landing area by various approaches depending on the specific CMUT fabrication workflow. Moreover, the disclosed approach can be employed in conjunction with other types of MEMS devices that employ a deformable membrane that can contact a landing area, such as certain types of MEMS pressure sensors, certain types of MEMS actuators, and so forth. Additionally, the pedestals 106 and isolation pedestals 506 may both be utilized in a single CMUT device, such that the bottom/sensing electrode 102 may include both a set of pedestals 106 and a set of isolation pedestals 506.

In accordance with a first embodiment, there is provided a method of manufacturing a micro-electro-mechanical system (MEMS) device. The method includes depositing and patterning one or more bottom dielectric layers on an integrated circuit substrate that has associated conductive components associated. The method also includes depositing and patterning one or more sensing electrodes on the bottom dielectric layer in electrical communication with the conductive components. The method further includes depositing a pedestal dielectric layer subsequent to the patterning of the sensing electrodes, and patterning one or more dielectric pedestals from the pedestal dielectric layer on the sensing electrodes. Also, the method includes forming one or more cavities on the integrated circuit substrate. These cavities include the sensing electrode and the dielectric pedestals disposed therein. Thereafter, the method includes disposing at least one movable membrane over the at least one cavity.

In accordance with a second embodiment, there is provided a semiconductor device. The semiconductor device includes at least one membrane, and an integrated circuit substrate. The integrated circuit substrate includes one or more conductive components disposed within a first dielectric layer on the substrate, with the conductive components interconnected with respective integrated circuit components. The substrate further includes one or more sensing electrodes electrically coupled to the conductive components, and one or more dielectric pedestals positioned within a landing area of the sensing electrode. In addition, the semiconductor device includes at least one cavity that is formed by the membrane positioned over the sensing electrode.

In accordance with a third embodiment, there is provided a capacitive micromachined ultrasonic transducer (CMUT). The capacitive micromachined ultrasonic transducer includes an integrated circuit substrate and a sensing electrode positioned on the integrated substrate that has a sidewall forming a wall of an isolation trench adjacent the sensing electrode. The capacitive micromachined ultrasonic transducer further includes a plurality of dielectric pedestals patterned in a pedestal dielectric layer on the sensing electrode, and a membrane that is positioned over the sensing electrode which forms a cavity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a micro-electro-mechanical systems (MEMS) device, comprising:
depositing and patterning, on an integrated circuit substrate, at least one bottom dielectric layer, the integrated circuit substrate having a plurality of conductive components associated therewith;
depositing and patterning at least one sensing electrode on the at least one bottom dielectric layer in electrical communication with at least one of the plurality of conductive components;
depositing a pedestal dielectric layer subsequent to the patterning of the at least one sensing electrode;
patterning at least one dielectric pedestal in the pedestal dielectric layer on the at least one sensing electrode;
forming at least one cavity on the integrated circuit substrate, wherein the at least one sensing electrode and the at least one dielectric pedestal are disposed in the at least one cavity; and
disposing at least one movable membrane over the at least one cavity.

2. The method of claim 1, wherein the disposing of the at least one movable membrane includes bonding a carrier wafer to the integrated circuit substrate, wherein the carrier wafer includes the at least one membrane which is disposed over the at least one cavity when the carrier wafer is bonded.

3. The method of claim 2, wherein the at least one dielectric pedestal is positioned within a landing area on the at least one sensing electrode of the at least one membrane.

4. The method of claim 3, wherein the at least one dielectric pedestal comprises an isolation pedestal positioned within an isolation cavity.

5. The method of claim 3, wherein a plurality of dielectric pedestals are patterned within the landing area.

6. The method of claim 5, wherein the landing area corresponds to greater than or equal to 60% of the at least one sensing electrode area.

7. The method of claim 6, wherein the at least one dielectric pedestal defines greater than or equal to 1.5% of the landing area.

8. The method of claim 5, wherein each of the plurality of dielectric pedestals includes a pedestal diameter (“P”) and a pedestal height (“H”) defining an aspect ratio of “H/P”, and wherein the aspect ratio H/P is in the range of 0.025~0.2.

9. The method of claim 8, wherein the pattern of dielectric pedestals comprise a predetermined pedestal to pedestal pitch ratio (“S”) that is in the range of less than or equal to 80%.

10. The method of claim 1, further comprising depositing and patterning at least one top dielectric layer subsequent to the patterning of the at least one dielectric pedestal.

11. The method of claim 1, wherein the at least one sensing electrode is a bottom electrode of a capacitive micromachined ultrasonic transducer (CMUT) unit.

12. A method of manufacturing a semiconductor device, comprising:
forming a plurality of conductive components disposed within a first dielectric layer on a substrate, the plurality of conductive components interconnected with a respective plurality of integrated circuit components;
forming at least one sensing electrode electrically coupled to at least one of the plurality of conductive components;
forming a plurality of dielectric pedestals disposed within a landing area of the at least one sensing electrode; and
forming at least one cavity using at least one moveable membrane positioned over the at least one sensing electrode.

13. The method of claim 12, wherein the plurality of dielectric pedestals are formed as isolation pedestals positioned within a corresponding isolation cavity.

14. The method of claim 12, wherein the landing area corresponds to greater than or equal to 60% of the area of the at least one sensing electrode.

15. The method of claim 14, wherein each of the plurality of dielectric pedestals comprises a top surface area greater than or equal to 1.5% of the landing area.

16. A method of manufacturing a capacitive micromachined ultrasonic transducer (CMUT), comprising:
depositing and patterning a sensing electrode on an integrated substrate, the sensing electrode formed to have a sidewall forming a wall of an isolation trench adjacent to the sensing electrode;
depositing and patterning a plurality of dielectric pedestals on the sensing electrode; and
disposing a moveable membrane over the plurality of dielectric pedestals, the moveable membrane forming at least one cavity between the moveable membrane and the sensing electrode, and the moveable membrane formed to contact the plurality of dielectric pedestals during an operation of the CMUT.

17. The method of claim 16, wherein the plurality of dielectric pedestals are isolation pedestals formed within corresponding isolation cavities.

18. The method of claim 16, wherein the plurality of dielectric pedestals are formed within a landing area on the sensing electrode.

19. The method of claim 18, wherein the landing area corresponds to greater than or equal to 60% of a surface area of the sensing electrode, and wherein each of the plurality of dielectric pedestals comprises a top surface area greater than or equal to 1.5% of the landing area.

20. The method of claim 19, wherein the disposing of the moveable membrane includes bonding a carrier wafer to the integrated circuit substrate, the carrier wafer including the moveable membrane which is disposed over the at least one cavity when the carrier wafer is bonded to the integrated circuit substrate.
